(19) United States
(12) Patent Application Publication
(10) Pub. No.: US 2026/0011526 A1
(43) Pub. Date: Jan. 8, 2026

(54) MULTI-BEAM PARTICLE BEAM SYSTEM AND METHOD FOR OPERATING THE SAME

(71) Applicant: Carl Zeiss MultiSEM GmbH, Oberkochen (DE)

(72) Inventors: Alexander WERTZ, Aalen (DE); Alexander HUEBEL, Schorndorf (DE); Markus SCHUSTER, Nattheim (DE); Tobias ZENGERLE, Oberkochen (DE); Wolfgang SINGER, Aalen (DE)

(21) Appl. No.: 19/326,290

(22) Filed: Sep. 11, 2025

Related U.S. Application Data
(63) Continuation of application No. PCT/EP2024/025093, filed on Feb. 28, 2024.

(30) Foreign Application Priority Data
Mar. 22, 2023 (DE) 10 2023 202 582.5

(51) Int. Cl. H01J 37/26; H01J 37/09; H01J 37/244

(52) U.S. Cl. CPC H01J 37/265; H01J 37/09; H01J 37/244; H01J 2237/0225; H01J 2237/0453; H01J 2237/1532; H01J 2237/1534; H01J 2237/24514; H01J 2237/24564; H01J 2237/2485; H01J 2237/282

(57) ABSTRACT

A multi-beam particle microscope with a micro-optical unit for generating the multiplicity of individual beams is disclosed. The micro-optical unit comprises a mechanism for setting and maintaining an unchanging imaging property of the multiplicity of individual beams. In one example, the micro-optical unit comprises at least one measuring apparatus used to sense a change in length, a change in distance, a contamination or degradation of a component of the micro-optical unit during operation. A multi-beam particle microscope comprises a control unit which establishes an effect on at least one individual beam from a change in length, a change in distance, a contamination or degradation of the component. A multi-beam particle microscope also comprises a compensation element for compensating the effect on the at least one individual beam. According to a method for operating a multi-beam particle microscope, a remaining service life of the multi-beam particle microscope which meets a demand with respect to a wafer inspection is also established.

### CROSS-REFERENCE TO RELATED APPLICATIONS

The present application is a continuation of, and claims benefit under 35 USC 120 to, international application No. PCT/EP2024/025093, filed Feb. 28, 2024, which claims benefit under 35 USC 119 of German Application No. 10 2023 202 582.5, filed Mar. 22, 2023. The entire disclosure of each of these applications is incorporated by reference herein.

### FIELD

The disclosure relates to multi-beam particle beam systems. For example, the disclosure relates to a multi-beam particle microscope having a control unit which, during operation, ensures an imaging property of the multi-beam particle microscope, and to an associated method of operating the multi-beam particle microscope.

### BACKGROUND

With the ongoing development of ever smaller and ever more complex microstructures such as semiconductor components, there is a general desire to further develop and optimize planar production techniques and inspection systems for inspecting small dimensions of the microstructures. Therefore, there is a general for an inspection mechanism which can be used with high throughput to examine the microstructures on wafers with high accuracy.

Typical silicon wafers used in the production of semiconductor components have diameters of up to 300 mm. Each wafer is subdivided into repeating regions (“dies”). A semiconductor apparatus comprises a plurality of semiconductor structures, which are produced in layers on a surface of the wafer by planar integration techniques. Semiconductor wafers typically have a plane surface on account of the production processes. The structure size of the integrated semiconductor structures in this case extends from a few um to the critical dimensions (CD) of 5 nm, and the structure sizes will become even smaller in the near future; in future, structure sizes or critical dimensions (CD) are expected to be less than 3 nm, for example 2 nm, or even less than 1 nm. For several applications, the desired accuracy of a measurement provided by inspection equipment is even higher, for example by a factor of two or one order of magnitude. By way of example, a width of a semiconductor feature are measured with an accuracy of below 1 nm, for example 0.3 nm or even less, and a relative position of semiconductor structures are determined with an overlay accuracy of below 1 nm, for example 0.3 nm or even less.

The MSEM, a multi-beam electron microscope, is a relatively new development in the field of charged particle systems (charged particle beam microscopes, CPMs). For example, a multi-beam electron microscope is disclosed in U.S. Pat. No. 7,244,949 B2 and in US 2019/0355544 A1. In the case of a multi-beam electron microscope or MSEM, a sample is irradiated simultaneously with a multiplicity of individual electron beams, which are arranged in a field or raster. By way of example, 4 to 10,000 individual electron beams can be provided as primary radiation, with each individual electron beam being separated from an adjacent individual electron beam by a pitch of 1 to 200 micrometers. By way of example, an MSEM has approximately 100 separated individual electron beams (“beamlets”), which are arranged for example in a hexagonal raster, wherein the individual electron beams are separated by a distance of approximately 10 μm. The multiplicity of individual charged particle beams (primary beams) are focused on a surface of a sample to be examined by way of a common objective lens. By way of example, the sample can be a semiconductor wafer which is secured to a wafer chuck mounted on a movable stage. When the wafer surface is illuminated by the charged primary individual particle beams, interaction products, for example secondary electrons or backscattered electrons, emanate from the surface of the wafer. Their start points correspond to those locations on the sample onto which the multiplicity of primary individual particle beams are focused in each case. The amount and the energy of the interaction products depend on the material composition and the topography of the wafer surface. The interaction products form a plurality of secondary individual particle beams (secondary beams), which are collected by the common objective lens and imaged on a detector, which is arranged in a detection plane, by a projection imaging system of the multi-beam electron microscope. The detector comprises multiple detection regions, each of which comprises multiple detection pixels, and the detector acquires an intensity distribution for each of the secondary individual particle beams. An image field of, for example, 100 μm×100 μm is obtained in the process.

Certain known multi-beam electron microscopes comprise a sequence of electrostatic and magnetic elements. At least some of the electrostatic and magnetic elements are adjustable in order to adapt the focus position and the stigmation of the multiplicity of charged individual particle beams. Such multi-beam systems moreover comprise at least one crossover plane of the primary or the secondary charged individual particle beams. Moreover, such systems comprise detection systems in order to facilitate the adjustment. Such multi-beam electron microscopes comprise at least one beam deflector (“deflection scanner”) for collective scanning of a region of the sample surface via the multiplicity of primary individual particle beams in order to obtain an image field of the sample surface.

In such a multi-beam electron microscope, the multiplicity of individual beams are generated using a first multi-aperture plate or filter plate with a multiplicity of first apertures in a first raster arrangement. The multiplicity of individual beams subsequently pass through further multi-aperture plates, for example a second multi-aperture plate with second apertures, for example with an array of active electrostatic elements. Ideally, the first apertures are round and generate a multiplicity of ideal individual beams. Ideally, each individual beam passes through an assigned second aperture in centered fashion in the geometric center of the second aperture. In typical examples, there are further multi-aperture plates with further apertures in addition to the first and second multi-aperture plates.

A multi-aperture plate may deform or degrade during the operation of a multi-beam microscope. For example, this can give rise to the effect that at least one individual beam no longer passes centrally through a second aperture of a second multi-aperture plate.

For example, this can give rise to the effect that at least one individual beam no longer passes centrally through an electrostatic field generated in a second aperture. Further, an electrostatic field generated in a second aperture may be disturbed by a degradation or contamination. Further, an electrostatic field generated in a second aperture during operation may be disturbed by increased roughness. A contamination may give rise to creepage currents which could disturb measurement or control signals.

WO 2023/001401 A1 has disclosed the possibility of arranging, on a first multi-aperture plate, detectors which measure an absorbed beam current of an incident beam of charged particles, and this can for example be used to control a source current. However, it is believed that this measured beam current is not able to provide any information about the state of a multi-aperture plate. Instead, disturbances on a multi-aperture plate occurring during operation may be overlaid on the absorbed beam current and consequently interfere with the measurement of the absorbed beam current and lead to an incorrect control of the source current.

In summary, during the operation of a multi-beam microscope with increased demands with respect to resolution and accuracy, disturbances arising during operation may arise at the multiplicity of individual beams, and this can make a predetermined method for generating the individual beams more difficult. For example, this may lead to individual beams which deviate from a predetermined position in a raster arrangement or which deviate from a predefined shape.

### SUMMARY

The disclosure seeks to provide an improved multi-beam particle microscope which is suitable for the increased demands with respect to resolution and accuracy when performing a wafer inspection task. The disclosure seeks to provide a method for operating a multi-beam microscope, with which it is possible to observe the increased demands with respect to resolution and accuracy of wafer inspection tasks during operation.

A multi-beam particle microscope is disclosed in a first exemplary embodiment. The multi-beam particle microscope comprises an apparatus for sensing a property of at least one multi-aperture plate during the operation of the multi-beam particle microscope for performing a wafer inspection task. The multi-beam particle microscope also comprises a control device designed to determine a prediction of a negative effect on the system performance from the one property.

A multi-beam system comprises a particle source for generating a particle beam and a micro-optical unit comprising at least one multi-aperture plate or filter plate for generating the multiplicity of individual beams. A multi-beam system also comprises a beam splitter and an objective lens for generating a multiplicity of focus points in an image plane. There is an increased demand on the multiplicity of focus points in the image plane, with respect to attaining the imaging quality of the multiplicity of individual beams for a wafer inspection task.

In a multi-beam particle microscope, the multiplicity of individual beams are generated using a first multi-aperture plate, for example a filter plate with a multiplicity of first apertures in a first raster arrangement. The multiplicity of individual beams generated in a fixedly prescribed raster arrangement using the filter plate are influenced by an array of lenses or multi-pole elements. The influencing of at least one individual beam comprises at least a deflection, a focusing or a compensation of aberrations. Ideally, the first apertures are round or elliptical and generate a multiplicity of ideal individual beams.

The multiplicity of individual beams subsequently pass through further multi-aperture plates, for example a second multi-aperture plate. The second apertures of the second multi-aperture plate, for example having an array of active electrostatic or magneto-dynamic elements, are provided in a second raster arrangement, with the first and second raster arrangement being mapped onto one another by a similarity transform. Ideally, each individual beam passes an assigned second aperture in centered fashion in the geometric center of the second aperture. In typical examples, the first and the second multi-aperture plates are complemented by further multi-aperture plates with apertures in further raster arrangements that are each mathematically similar to the first raster arrangement.

In an example, the second raster arrangement is identical to the first raster arrangement, and the multiplicity of individual beams run through the filter plate and the second or further multi-aperture plate in parallel. In a further example, a filter plate with a multiplicity of apertures in the first raster arrangement is situated in a divergent electron beam, and the second raster arrangement of the second multi-aperture plate corresponds to a stretched first raster arrangement. In a further example, a magnetic field is situated between the filter plate and the second multi-aperture plate, and the second raster arrangement emerges from the first raster arrangement by way of a spiral similarity. In any case, each individual beam can pass through an assigned second aperture in a predetermined position in each case, for example in centered fashion in the geometric center of the assigned second aperture.

A multi-aperture plate may deform, become contaminated or degrade during the operation of a multi-beam microscope. A multi-beam particle microscope according to the first embodiment therefore can comprise a measuring apparatus for determining the deformation, contamination or degradation of at least one multi-aperture plate. The measuring apparatus may comprise a strain sensor or an interdigital structure for sensing a change in length, a capacitive sensor for sensing a change in distance, and/or an ammeter for sensing a leakage current. A strain sensor can be designed as an optical strain sensor, for example a fiber Bragg grating sensor. A strain sensor can be designed as a strain gauge. It is also possible to provide apparatuses which determine a temperature distribution over a multi-aperture plate. A deformation of a multi-aperture plate can be deduced from the temperature distribution.

A deformation may comprise a lateral deformation or comprise a bending or a torsion of a multi-aperture plate in the beam direction. Deformations may also comprise deformations of a load-bearing structure for a multi-aperture plate, arising for example due to a temperature gradient. Deformations of a load-bearing structure may lead to a deformation of a multi-aperture plate or to a positional change or tilt of a multi-aperture plate. A deformation may be permanent or reversible.

A degradation may comprise a change in specific resistances, for example as a result of radiation-induced material modifications or thermal diffusion. A degradation may comprise a change in the current or voltage bearing capacity of printed circuit boards. Further, the roughness of a surface may be modified as a consequence of a degradation or contamination.

The multi-beam system according to the first exemplary embodiment can comprise a control unit connected to at least one measuring apparatus of a multi-aperture plate. During operation, the measuring apparatus supplies a measurement signal to the control unit, and the control unit is configured to determine a change in a shape, a contamination or a degradation of the at least one multi-aperture plate from the measurement signal during operation. The control unit is further designed to determine an effect on at least one individual beam from the change in shape, a contamination or a degradation of the at least one multi-aperture plate.

As a result of the indirect determination of an effect on at least one individual beam, it is possible to dispense with a time-consuming measurement of the imaging properties of each individual beam. From the change in shape, a contamination or a degradation of at least one multi-aperture plate, it is possible to deduce an effect on at least one individual beam during operation, and hence on the imaging properties of the at least one individual beam, without interrupting a wafer inspection task. It is thus possible to ensure that a demand on the imaging properties of a wafer inspection task with increased throughput is met.

The effects occurring as a consequence of a change in shape, a contamination or a degradation of a multi-aperture plate may be determined in advance. For example, the deformation of a multi-aperture plate can give rise to the effect that at least one individual beam no longer passes centrally through an aperture of a multi-aperture plate. For example, there may be a deformation in a first multi-aperture plate or filter plate, with the result that the multiplicity of individual beams are already generated in a deviating first raster arrangement and at least one individual beam no longer passes centrally through a second aperture of the second multi-aperture plate. For example, a deformation may be present in a second multi-aperture plate, with the result that at least one individual beam no longer passes centrally through a second aperture of the second multi-aperture plate.

For example, this can give rise to the effect that at least one individual beam no longer passes centrally through an electrostatic field generated in a second aperture. For example, this may give rise to an unwanted deflecting effect on an individual beam in addition to a lens effect of an electrostatic lens field. In the case of a multi-pole stigmator, this may for example generate an unwanted aberration for an individual beam. In the case of a deflector, an individual beam may be displaced out of the linear field region and this may cause an unwanted different deflection of the individual beam.

Further, an electrostatic field generated in an aperture may be disturbed by a time-varying degradation or contamination. Further, an electrostatic field modified in an aperture during operation may be disturbed by increased roughness.

These time-varying effects and their undesirable influences on imaging properties of individual beams can be detected by the multi-beam particle microscope. A multi-beam particle microscope according to an embodiment therefore comprises a control unit configured to determine an unwanted effect on the properties of at least one individual beam from the deformation, contamination or degradation of a multi-aperture plate. According to an embodiment, the control unit is also configured to use the unwanted effect on the properties of the at least one individual beam as a basis for making a prediction as to whether, and for how much longer, an inspection task can still be performed while meeting predetermined desired properties. For example, a need for servicing, cleaning, recalibration or exchange of at least one multi-aperture plate can be determined using the prediction.

In an example, a multi-beam particle microscope further comprises a mechanism for compensating the negative influence or effect on at least one individual beam. In an example, the multi-beam system further comprises at least one active multi-aperture plate for influencing the multiplicity of individual beams.

The control device can be designed to use the prediction of the negative effect on the imaging properties as a basis for generating a correction signal used to control the mechanism for compensating the negative effect. A compensation element can be designed for at least partial compensation of the effect on at least one individual beam, and the control unit can be configured to establish a control signal for the compensation element and supply the control signal to the compensation element.

A multi-beam particle microscope according to an embodiment comprises a mechanism for compensating the undesired effect. The mechanism may comprise elements of the second multi-aperture plate, whose e.g. electrostatic elements are controlled differently in order to compensate for the beam offset of an individual beam. The mechanism may also comprise further multi-aperture plates, for example a deflector array for compensating unwanted beam deflections or a stigmator array for compensating unwanted aberrations. Unwanted aberrations may also comprise changes in the cross-sectional area of an individual beam in a plane parallel to an image plane.

In an example, a compensation element comprises an active multi-aperture plate having an array made of multi-pole elements. In an example, the control device is further designed to determine a service life prediction, within which the multi-beam system can be operated in line with the demands of an inspection task.

In an example, the multi-beam system also comprises a displaceable measuring mechanism and a positioning element for positioning the displaceable measuring mechanism for inspecting at least one aperture of a multi-aperture plate. For example, this may improve sensing of a contamination or roughness within the interior of an aperture. A multi-beam system may further comprise a cleaning chamber and a positioning device for positioning at least one multi-aperture plate in the cleaning chamber. The cleaning chamber can comprise cleaning apparatuses, for example plasma sources for plasma cleaning or heating elements for a thermal treatment. A cleaning chamber may also be provided for the replacement of a multi-aperture plate. At least one measuring mechanism for inspecting at least one aperture of a multi-aperture plate can be arranged in the cleaning chamber. For example, this can allow sensing of a contamination or roughness within the interior of an aperture.

In general, a multi-beam system can be sensitive to deformations of the filter plate whose multiplicity of apertures are used to generate the multiplicity of individual beams. For example, as a result of a deformation of the filter plate, an aperture may be furnished with an elliptical shape vis-à-vis the incident electron beam. In an exemplary embodiment, the multiplicity of aperture openings of the filter plate of the multi-beam system are designed with an elliptical cross-sectional shape, wherein the elliptical shape is designed in accordance with a subsequent beam deflection of each individual beam such that each individual beam has the same round cross-sectional area in a plane parallel to the image plane. In this example, a deformation of the filter plate may provide an aperture with a shape vis-à-vis the incident electron beam which deviates from the desired elliptical shape. In an example, the compensation element comprises two active multi-aperture plates for at least partial compensation of the effect on at least one individual beam, the control unit being designed such that, during operation, each individual beam maintains a round cross-sectional area in a plane parallel to the image plane.

In a second embodiment, a method for operating a multi-beam system is disclosed, by which the increased demands on the resolution and accuracy of a wafer inspection task can be met during operation. The method comprises sensing at least one property of at least one multi-aperture plate during operation. The method also comprises a prediction of a negative effect on the system performance on the basis of the one property. While performing an inspection task on a wafer using a multiplicity of individual beams, measurement signals are acquired from a measuring apparatus connected to at least one multi-aperture plate of a micro-optical unit. The method comprises the establishment of a current type of load on a multi-aperture plate from the measurement signals, wherein a type of load comprises a longitudinal extension, a deformation, a contamination or a degradation of the at least one multi-aperture plate. The method comprises the determination of an effect of the current type of load on the imaging properties of at least one individual beam. An effect might be a deviation in a desired beam direction, a deviation of a desired beam position, or a beam aberration of an individual beam. For example, a beam aberration might be an astigmatism or a comatic aberration. A beam aberration can be a deviation from a round shape of a cross-sectional area of at least one individual beam in a plane parallel to an image plane. The acquisition, establishment and determination steps may be performed repeatedly during an inspection task. The establishment of the current load diagram may comprise a model-based analysis or a finite element analysis. Measurement signals and the respectively current load diagrams can be stored.

In an example, the method also comprises determining a measure for compensating the effect on the at least one individual beam. In that case, the method comprises deriving at least one control signal for at least one compensation element for at least partial compensation of the effect on the imaging properties of the at least one individual beam and the supply of the at least one control signal to the at least one compensation element.

In an example, the method comprises as a further step inserting a measuring mechanism for inspecting at least one aperture of at least one multi-aperture plate and the sensing of a contamination, a shape deviation or a roughness within at least one aperture.

In an example, the method also comprises determining a service life prediction. In that case, the method also comprises deriving a remaining service life of the multi-beam system from at least one load diagram, with an operation of the multi-beam system meeting a demand on the imaging properties of the multiplicity of individual beams being ensured within the service life. The method also comprises initiating servicing, cleaning or a replacement of the at least one multi-aperture plate. To this end, displacing the at least one multi-aperture plate or micro-optical unit into a cleaning chamber may be provided as a further step. Servicing may comprise a mechanical treatment, within which deformations or positional changes of multi-aperture plates are corrected, for example by way of micro-actuators.

With the method steps of the second embodiment, it is possible to ensure the operation of a multi-beam system which meets the desired properties of a wafer inspection task over a longer period of time. Servicing or replacement of a micro-optical unit component can be predicted, and hence controlled, using the method steps of the second embodiment. This ensures a longer operating time of a multi-beam system. With the method steps of the second embodiment, it is possible to ensure uniformity and isotropy of an imaging property of the multiplicity of individual beams, even during operation with a high throughput.

In a third embodiment, there is a provision of a multi-beam system with which uniformity and isotropy of an imaging property of the multiplicity of individual beams is ensured, even during operation with a high throughput. The multi-beam system according to the third embodiment comprises a micro-optical unit having a filter plate comprising a multiplicity of apertures for generating a multiplicity of individual beams. The multi-beam system also comprises an objective lens which during operation generates a multiplicity of focus points of the multiplicity of individual beams in an image plane and a beam splitter which deflects the multiplicity of individual beams through a deflection angle greater than 0°. For example, the deflection angle may encompass 3° to 20°, such as 4° to 10°. The filter plate comprises a multiplicity of apertures with an elliptical cross-sectional shape, whose elliptical shape is designed in accordance with a subsequent beam deflection of each individual beam such that each individual beam has the same round cross-sectional area in a plane parallel to the image plane. This can help ensure the uniformity of the isotropy of an imaging property of each individual beam in the image plane. The elliptical cross-sectional shape can be designed so as to compensate an effect of the deflection angle of the beam splitter on the cross-sectional area of the multiplicity of individual beams in the plane parallel to the image plane. The multi-beam system may also comprise at least one active multi-aperture plate, wherein the at least one active multi-aperture plate comprises a multiplicity of deflectors which deflect each individual beam in an axial direction through a predetermined angle. In that case, each aperture can have an individual elliptical cross-sectional shape for compensating an effect of the respective predetermined deflection of the at least one active multi-aperture plate. In an example, the diameters of the apertures with elliptical cross-sectional shape additionally have a parameter dependent on the position of an individual beam in order to compensate or preserve an image shell error (Petzval field curvature) and an image plane tilt.

In an example of the third embodiment, the filter plate or at least one active multi-aperture plate has available a measuring apparatus which supplies a measurement signal to a control unit of the multi-beam system. The control unit is configured during operation to determine a change in shape, a contamination or a degradation of the filter plate or the at least one active multi-aperture plate from the measurement signal. The measuring apparatus may comprise at least one of the following measuring mechanisms: a strain sensor or an interdigital structure for sensing a change in length, a capacitive sensor for sensing a change in distance, and/or an ammeter for sensing a leakage current. A strain sensor can be designed as an optical strain sensor, for example a fiber Bragg grating sensor. In an example, the multi-beam system also comprises at least one compensation element for at least partial compensation of an effect of the change in shape, the contamination or the degradation of the filter plate or the at least one active multi-aperture plate. The control unit can be designed to establish and supply a control signal for the compensation element from the change in shape, the contamination or the degradation. A compensation element may comprise an active multi-aperture plate having an array of multi-pole elements. A multi-beam system may further comprise a cleaning chamber and a positioning device for positioning the filter plate or the at least one active multi-aperture plate in the cleaning chamber.

In an embodiment of the disclosure, a measuring apparatus for generating a measurement signal for determining a contamination or a degradation of at least one multi-aperture plate comprises a differential ammeter DI. The differential ammeter DI can be used to measure a difference between a current flowing toward an active multi-aperture plate and a current flowing away from the active multi-aperture plate. A leakage current as a consequence of contamination or degradation can be deduced from the deviation of the current difference from a predetermined target value.

In an embodiment of the disclosure, a micro-optical unit comprises an electrically conductive dissipation layer arranged between two multi-aperture plates, the dissipation layer being insulated from the adjacent multi-aperture plates by insulators. For example, a first multi-aperture plate can be a filter plate and a second multi-aperture plate can be an active multi-aperture plate. The conductive dissipation layer is connected to ground. Hence, leakage currents from the first or second multi-aperture plate are dissipated via the conductive dissipation layer. Hence, a current measurement of an absorbed particle current of a filter plate is not falsified by leakage currents, for example. Hence, an active multi-aperture plate control is not falsified by leakage currents, for example.

Additionally, the conductive dissipation layer may be connected to the ground via an ammeter such that arising leakage currents can be measured.

The various embodiments and aspects of the disclosure can be combined wholly or partly with one another, provided that no technical contradictions arise as a result.

### BRIEF DESCRIPTION OF THE DRAWINGS

The disclosure will be understood even better with reference to the accompanying figures. In the figures:

FIG. 1 shows a multi-beam system;

FIG. 2 shows an example of components of a multibeam system;

FIGS. 3A-3C illustrate a design of a beam shaping apparatus having a filter plate and at least one active multi-aperture plate;

FIGS. 4A-4F illustrate a deformation of a multi-aperture plate or creepage currents during operation, and a mechanism for measuring a creepage current;

FIGS. 5A-5D illustrate examples of measuring mechanisms for establishing a deformation of a multi-aperture plate;

FIG. 6 shows an example of a measuring mechanism for inspecting apertures;

FIG. 7 shows an example of an arrangement having an inspection, cleaning and replacement position;

FIGS. 8A-8D show examples of effects arising due to a deformation of a multi-aperture plate;

FIGS. 9A-9D show examples of mechanisms for compensating an effect which arises due to a deformation of a multi-aperture plate; and

FIG. 10 illustrates the method steps of a method for operating a multi-beam system.

### DETAILED DESCRIPTION

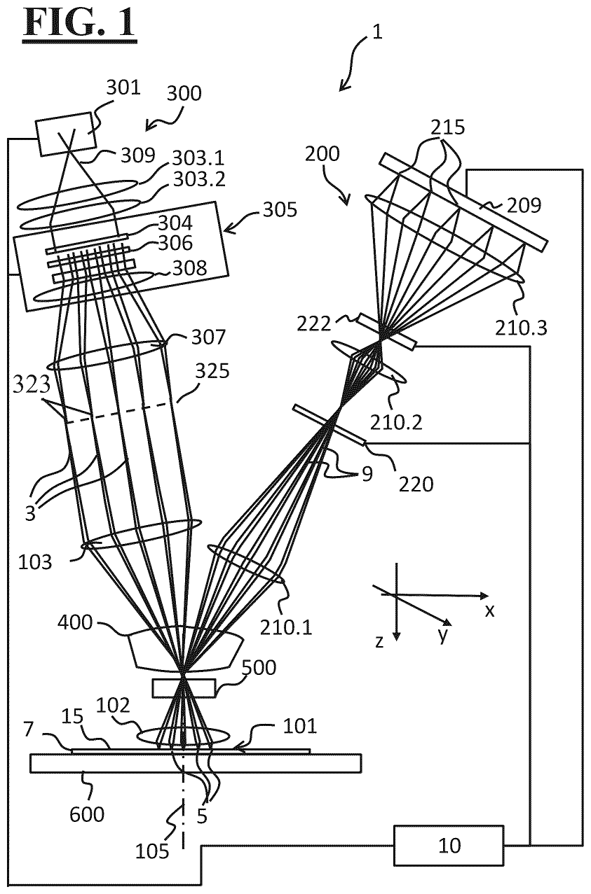

FIG. 1 schematically shows a multi-beam particle microscope 1. The multi-beam particle microscope 1, also referred to as a multi-beam system 1 below, comprises a beam generating apparatus 300 having a particle source 301 for generating charged particles, for example an electron source. A divergent particle beam 309 is collimated by a sequence of condenser lenses 303.1 and 303.2, and impinges on a multi-aperture arrangement 305. The multi-aperture arrangement 305 comprises a plurality of multi-aperture plates 306 and a field lens 308. A multiplicity of individual particle beams 3 or individual electron beams 3 are generated by the multi-aperture arrangement 305 (also referred to as a micro-optical unit 305). Midpoints of apertures in the micro-optical unit 305 are arranged in a raster arrangement in a first field which is imaged onto a further raster arrangement formed by beam spots 5 in an object plane 101. The distance between the midpoints of beam spots 5 in the object plane 101 can be 5 μm, 10 μm or 100 μm, for example. The pitches of the apertures in a multi-aperture plate are 100 μm, for example. The diameters D of the apertures are smaller than the pitch of the midpoints of the apertures; examples of the diameters are 0.2 times, 0.4 times and 0.8 times the distances between the midpoints of the apertures.

The micro-optical unit 305 and a field lens 307 are configured to generate a multiplicity of focus points 323 of primary beams 3 in a raster arrangement on an intermediate image surface 325. The surface 325 need not be a plane surface but rather can be a spherically curved surface in order to account for an image field curvature of the subsequent particle-optical system.

The multi-beam particle microscope 1 further comprises a system of electromagnetic lenses 103 and an objective lens 102, which image the beam foci 323 with reduced size from the intermediate image surface 325 into the object plane 101. In between, the first individual particle beams 3 pass through the beam splitter 400 and a first collective beam deflector or scanner 500, by which the multiplicity of first individual particle beams 3 are deflected during operation and the image field is scanned. For example, the first individual particle beams 3 incident in the object plane 101 form a substantially regular field. By way of example, the field formed by the incidence locations 5 can have a rectangular or hexagonal symmetry.

The object 7 to be examined can be of any desired type, for example a semiconductor wafer, a lithography mask or a biological sample, and may comprise an arrangement of miniaturized elements or the like. The surface 15 of the object 7 is arranged in the object plane 101 of the objective lens 102. The objective lens 102 can comprise one or more electron-optical lenses. By way of example, this can be a magnetic objective lens and/or an electrostatic objective lens. The object 7, for example a wafer, is positioned on a displacement device or stage 600 with the surface 15 in the image plane 101. The surface 15 can be aligned perpendicular to an optical axis 105 of the objective lens 102, and the multiplicity of individual beams 3 are incident on the object in a manner substantially perpendicular to the object surface 15 and hence parallel to the optical axis 105.

The primary particles of the individual beams 3 incident on the object 7 generate interaction products, for example secondary electrons, backscattered electrons or primary particles which have experienced a reversal of movement for other reasons, and these interaction products emanate from the surface of the object 7 or from the first plane 101 or object plane 101. The interaction products emanating from the surface 15 of the object 7 are shaped by the objective lens 102 to form secondary particle beams 9. In the process, the secondary beams 9 pass through the beam splitter 400 downstream of the objective lens 102 and are supplied to a projection system 200. The projection system 200 comprises an imaging system having a plurality of electrostatic or magnetic lenses 210.1 to 210.3, a contrast stop 222 and a multi-particle detector 209. Incidence locations 215 of the second individual particle beams 9 on detection regions of the multi-particle detector 209 are located with a regular pitch in a third field. Exemplary values are 10 μm, 100 μm and 200 μm. Further, the projection system comprises a second collective deflector or scanner 220 which is used to keep the incidence locations 215 of the second individual particle beams 9 on the multi-particle detector 209 at a constant position.

The multi-beam particle microscope 1 furthermore comprises a computer system or control unit 10, which in turn can be embodied integrally or in multipartite fashion and which is designed both to control the individual particle optical components of the multi-beam particle microscope 1 and to evaluate and analyze the signals obtained by the multi-detector 209 or detection unit 209.

Further information relating to such multi-beam particle beam systems or multi-beam particle microscopes 1 and components used therein, such as, for instance, particle sources, multi-aperture plate and lenses, can be obtained from the international patent applications WO 2005/024881 A2, WO 2007/028595 A2, WO 2007/028596 A1, WO 2011/124352 A1 and WO 2007/060017 A2 and the German patent applications DE 10 2013 016 113 A1 and DE 10 2013 014 976 A1, the disclosure of which is incorporated in full in the present application by reference.

More stringent demands are placed on a multi-beam system 1, especially for a wafer inspection. For example, the resolution of each partial image captured using each individual particle beam should be identical within a tight tolerance, for example better than 3.5 nm, better than 3.0 nm or even better. For example, the resolution should be directionally independent; i.e., for example, the resolution in an x-direction should deviate from a resolution in a y-direction by no more than 5%. In this context, reference is also made to so-called H-V differences. Further, the positions of the individual beam spots 5 should be very stable so that the relative positions of the individual partial images remain stable and need not be corrected by a complicated computational correction of many partial image offsets. These stringent demands lead firstly to increased demands on the design of the micro-optical unit and secondly to increased demands during the operation of the micro-optical unit. A multi-beam system 1 according to an embodiment of the disclosure is designed to meet these increased demands even during operation. For example, the micro-optical unit 305 is designed to meet the increased demands. For example, the micro-optical unit 305 comprises an apparatus for monitoring the micro-optical unit during operation. For example, the micro-optical unit 305 comprises a mechanism for compensating effects that arise during operation. A micro-optical unit 305 comprises a sequence of at least one filter plate 304 and further multi-aperture plates 306.A micro-optical unit 305 may be designed as an aberration correction unit of the multi-beam particle microscope 1 according to the disclosure.

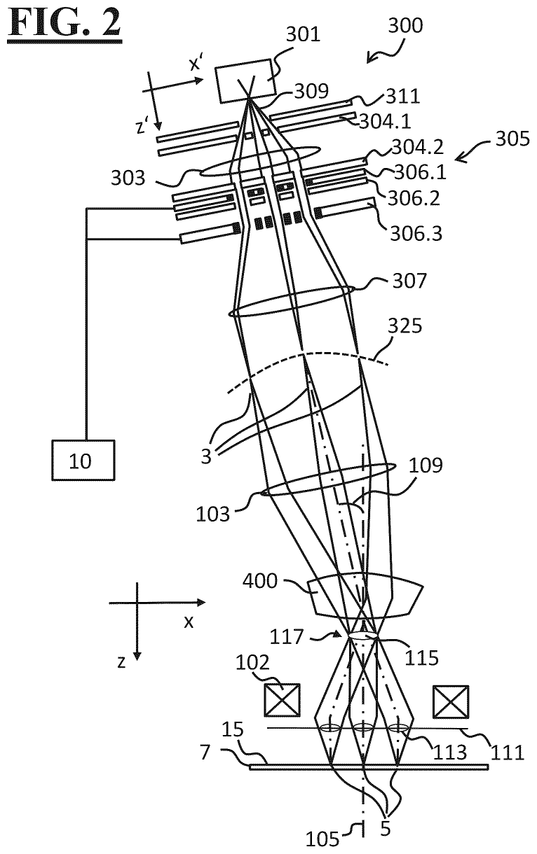

FIG. 2 shows a further embodiment of the beam generating apparatus 300. Disposed downstream of the electron source 301 there is a first stop 311 and a first multi-aperture plate or first filter plate 304.1 with a multiplicity of first apertures. The incident electron beam 309 is partially absorbed at the first filter plate 304.1. The primary particles passing through the multiplicity of the first apertures form the multiplicity of primary beams or individual particle beams 3. The first filter plate 304.1 is followed by a collimation lens or condenser lens 303 and further multi-aperture plates. The further multi-aperture plates comprise a second filter plate 304.2, a first active array element 306.1, a second active array element 306.2 and a third active array element 306.3. The second filter plate 304.2 and the active array elements 306.1 to 306.3 form a micro-optical unit 305. The micro-optical unit 305 is followed by a field lens 307 and the further components of the multi-beam system 1, with respect to which reference is made to FIG. 1 and the associated description. The multiplicity of primary beams are deflected through a deflection angle 109 into the direction of the optical axis 105 of the objective lens 102 by the beam splitter 400. The deflection angle 109 can be between 3° and 20°, such as between 4° and 10°. However, smaller or larger deflection angles 109 are also possible.

For wafer inspections in particular, there are increased demands on the isotropy of resolution and the uniformity of resolution of imaging for the multiplicity of particle beams. Isotropy of resolution means that a resolution in an x-direction deviates from a resolution in a y-direction perpendicular thereto by no more than 5%, for example. Optionally, the deviation is even less, for example 3% or even less. Additionally, the resolution of a first individual beam should deviate from a resolution of a second individual beam by no more than 5%, such as by less than 3%. Such isotropy and invariance of the resolution is achieved when the beam cross sections 115 in a pupil plane 117 are circular and have an identical diameter for all beams. Accordingly, the (real or virtual) beam cross sections 113 of all individual beams 3 are identical and circular in a plane 111 parallel to the image plane.

At each aperture, the active array elements 306.1 to 306.2 may comprise at least one to e.g. 8 or 12 electrodes in each case, whereby individual effects can be set during operation for each individual beam by way of applied voltages; for example, such effects are a lens effect with a circular electrode or else a deflecting effect or a beam correction (sometimes also referred to as stigmator effect) with multi-pole electrodes.

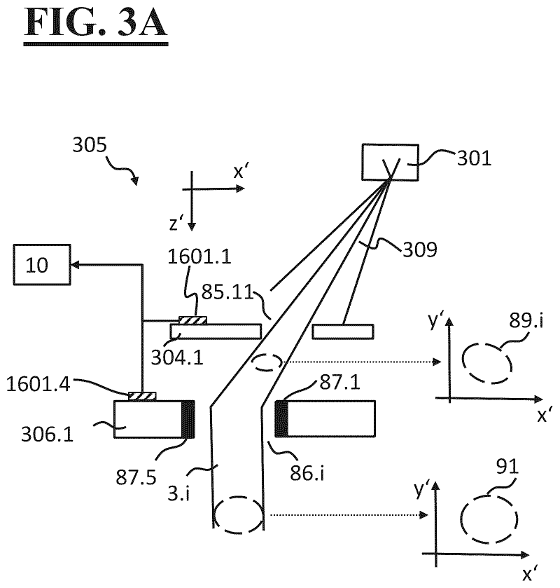

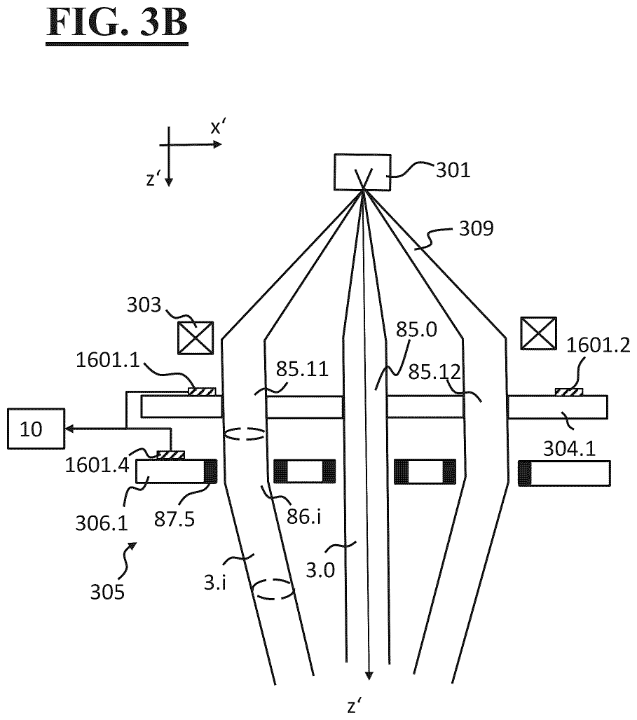

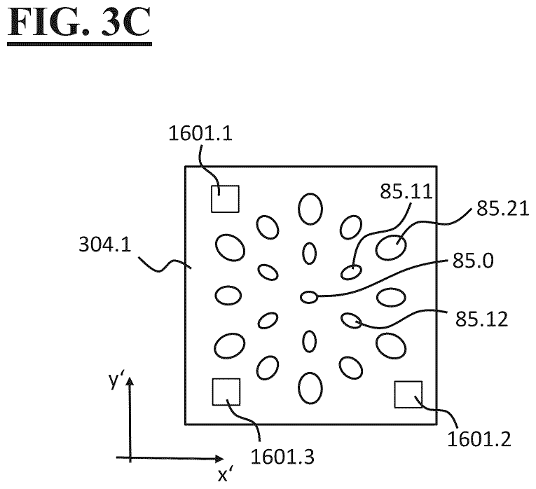

A detail of an exemplary micro-optical unit 305 is explained in detail in FIG. 3A. To simplify matters, only one aperture 85.11 for generating an individual beam is depicted. An electron beam 309 emanates from an electron source 301 and is filtered at a first aperture 85.11 in a first filter plate 304.1, with the result that the i-th individual beam 3.i is formed downstream thereof. In this case, the beam cross section 89.i of the individual beam 3.i corresponds to the aperture shape of the aperture 85.11. The individual beam 3.i subsequently passes through an aperture 86.i of a first active array element 306.1, which is designed as a deflector in this case. An electric field having a deflecting effect on the individual beam 3.i and aligning the latter parallel to the z′-axis is generated by way of the voltage applied to the two electrodes 87.1 and 87.5. In this example, the individual beam 3.i has a slightly elliptical beam cross section 91 following the deflection. To meet the increased demands on a multi-beam system 1 for the wafer inspection, it is desirable for the beam cross sections 91 to have a predetermined shape downstream of the micro-optical unit 305. In order to obtain a predetermined elliptical beam cross section 91, the aperture shape of the first beam-shaping aperture 85.11 has an elliptical design. In order to obtain the elliptical beam cross section 91 for each individual beam 3.j (with j=1, . . . , J), each aperture shape of each first beam-shaping aperture 85.j has an individual design.

FIG. 3C shows the plan view of a first filter plate 304.1 with a multiplicity of elliptical apertures 85.11, 85.12 and 85.21, which furthermore have different diameters and are designed such that, following the individually different deflection of each individual beam by an at least first active element 306.1, similar beam cross sections 91 arise and the aforementioned effect that the intermediate images of the source come to rest on the curved surface 321 sets in.

On account of the demand with respect to the uniformity of the resolution over all individual beams, all beam cross sections (113, 115) of each individual beam has the same diameter in the pupil plane 117 or in a plane 111 parallel to the image plane 101 (see FIG. 2). On account of the above-described isotropy demand on the resolution, the beam cross sections of each individual beam is circular in a plane 111 parallel to the image plane 101. The effect of the deflection angle 109 of the beam splitter 400 has a similar influence on the beam cross section of each individual beam to the beam deflection effect, described in FIG. 3A, as a result of the electrodes 87.1 and 87.5. To make this effect available, each first aperture 85 additionally is slightly elliptical in the direction of the beam deflection of the beam splitter 400. In FIG. 3C, the elliptical shape is depicted very exaggeratedly for the aperture 85.0 in representative fashion. This elliptical shape is overlaid equally for all apertures 85 in the x-direction, in accordance with the deflecting direction of the beam splitter 400. For example, the different aperture shapes of the first apertures in the first filter plate can be designed by tracing beams backward from the image plane 101.

It is now evident that the positions and the shapes of the apertures 85 and 86 and further apertures are predetermined very exactly and manufactured precisely, since slight deviations already lead to aberrations, incorrect beam deflection angles or non-round beam cross sections, which become noticeable as an astigmatism. Additionally, contaminations within the apertures may lead to deviations of the beam shape. In this context, deviations arising during the production can frequently be compensated for by way of a suitable calibration, for example of the deflection angles of the active element 306.1. However, some deviations only occur during operation. Such deviations may comprise a lateral deformation, a bending or a torsion of a multi-aperture plate in the beam direction. Deformations may also comprise deformations of a load-bearing structure for a multi-aperture plate, arising for example due to a temperature gradient. Deformations of a load-bearing structure may lead to a deformation of a multi-aperture plate or to a positional change or tilt of a multi-aperture plate. A deformation may be permanent or reversible.

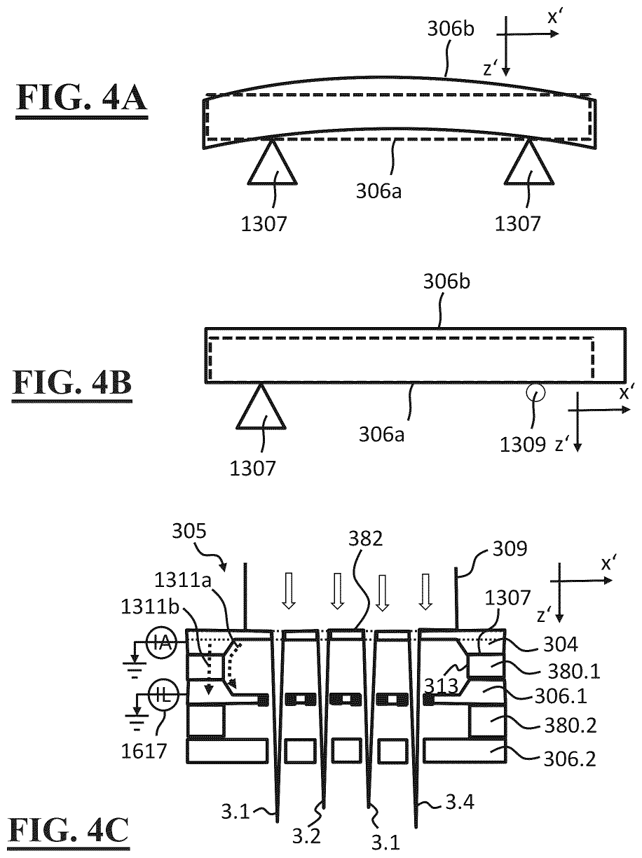

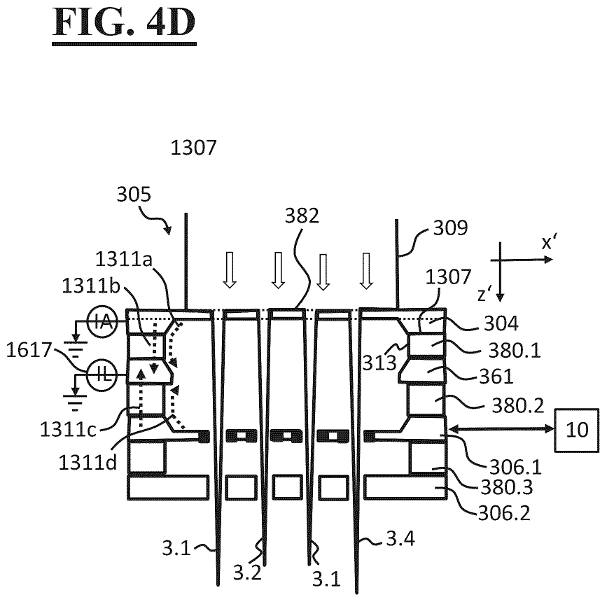

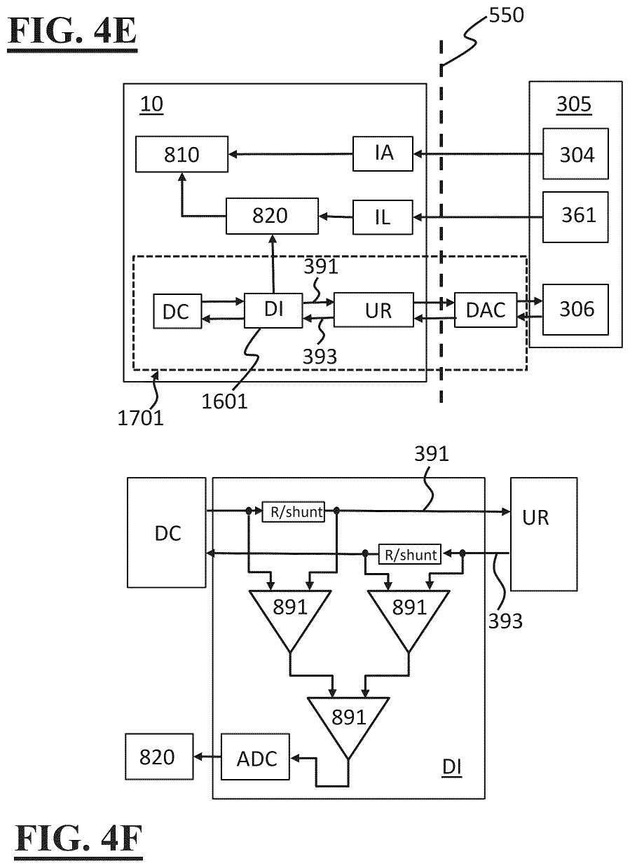

Some examples are shown in FIG. 4. FIG. 4A shows the case of a fixed arrangement of a membrane of a multi-aperture plate 306 with fixed connection points 1307. For example, such fixed connections 1307 occur if a plurality of multi-aperture plates 304, 306 are stacked on one another and securely connected to one another. The multi-aperture plate 306a has its desired shape (dashed line) in the cold state. During operation, the multi-aperture plate 306 heats up and the shape 306b bends (solid line) on account of the fixed mount. In this case, the bend is depicted substantially as a spherical bend; however, more complex bending shapes and more complex waviness of the membrane of a multi-aperture plate 304, 306 may also arise, depending on the fixed connection points 1307.

FIG. 4B shows a comparable case with a flexible mount on at least one flexible mounting point 1309. In this case, the multi-aperture plate 306 expands in its volume as a consequence of heating. However, the multi-aperture plate 306 need not necessarily bend on account of heating; instead, it can expand in terms of its length proceeding from a fixed mounting point 1307. Hence, there are positional deviations of the apertures (not depicted here). It becomes evident from both cases that diameters and positions and—like in the case with fixed mounting points 1307—even inclination angles of apertures may change during the operation. Further, temperature gradients may set in and additionally lead to a change in the shape of apertures. Some of these changes are reversible; however, others remain as permanent deformations of the membranes of the multi-aperture plates 306.

In addition to deformations, further deviations of the properties of a micro-optical unit 305 may occur during operation. Deviations may arise as a result of contamination or degradation, which may have an effect on individual beams. A degradation may comprise a change in specific resistances, for example as a result of radiation-induced material modifications or thermal diffusion. A degradation may comprise a change in the current or voltage bearing capacity of printed circuit boards. Further, the roughness of a surface may be modified as a consequence of a degradation or contamination.

An example is illustrated in FIG. 4C. A micro-optical unit 305 has a stacked construction in the example. The membrane layer 382 of the first filter plate 304 facing the incident electron beam 309 absorbs a large proportion of the incident primary particles and is therefore electrically connected to ground. The current IA flowing away can be measured, for example in order to use this to control a current of the source 301. The first filter plate 304 is connected to further multi-aperture plates 306, from which it is separated by an insulating layer 380, via fixed, for example extensive connection points 1307. For example, an insulating layer 380 may consist of silicon dioxide. During operation, carbon deposits, for example, which form a contamination layer 313 accumulate on the inner side of the insulating layer 380 facing the individual beams 3.1 to 3.4. Leakage currents or creepage currents 1311a, which lead to a charging of the first active multi-aperture plate 306.1, arise via the contamination layer 313. In the apertures in the first active multi-aperture plate 306.1, this charging leads to a change in the electric field strength and hence to a change of the effect of at least one active element on an individual beam 3.1.

Further, there is a degradation of the insulation layer 380. As a consequence, the insulation layer 380 may lose its insulating effect over a relatively long period of use and may become conductive; this may lead to further leakage currents 1311b which lead to further charging of the first active multi-aperture plate 306.1 during operation.

In general, a number of causes may add up as the cause for a deviation occurring during operation. For example, a mechanical deformation may be superimposed on a temperature change. For example, a mechanical deformation may have formed permanently or as an irreversible deformation which is superimposed by a deviation as a result of a temperature gradient during operation.

According to an embodiment of the disclosure, provision is therefore made for at least one measuring apparatus 1601 to be provided on at least one multi-aperture plate 304, 306 and be able to be used to monitor a deformation of a membrane of a multi-aperture plate 304, 306 during operation. Examples are shown in FIGS. 3A and 3B, with a first measuring apparatus 1601.1 on the first filter plate 304.1 and a second measuring apparatus 1601.4 on the active multi-aperture plate 306.1. In order to sense a load diagram or a deformation, a plurality of measuring apparatuses 1601 may also be arranged on at least one multi-aperture plate. An example is shown in FIG. 3B with the first filter plate 304.1, on which three measuring apparatuses 1601.1 to 1601.3 are arranged (only two of which are visible in the sectional image). In contrast to FIG. 3A, the incident electron beam is collimated by the condenser lenses 303 in FIG. 3B, with the result that the electron beam is incident on the filter plate 304.1 substantially perpendicularly. Each individual beam 3.i experiences an individual beam deflection by way of the active multi-aperture plate 306.1. Regarding the further description of FIG. 3B, reference is made to the description of FIG. 3A.

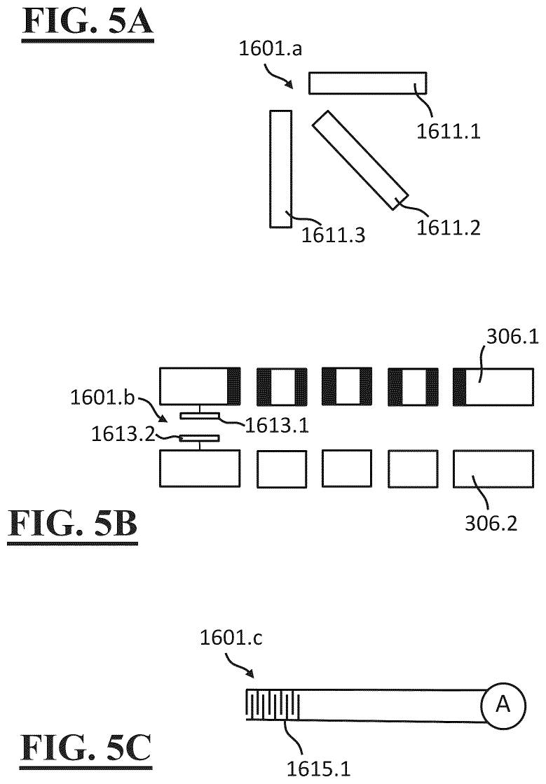

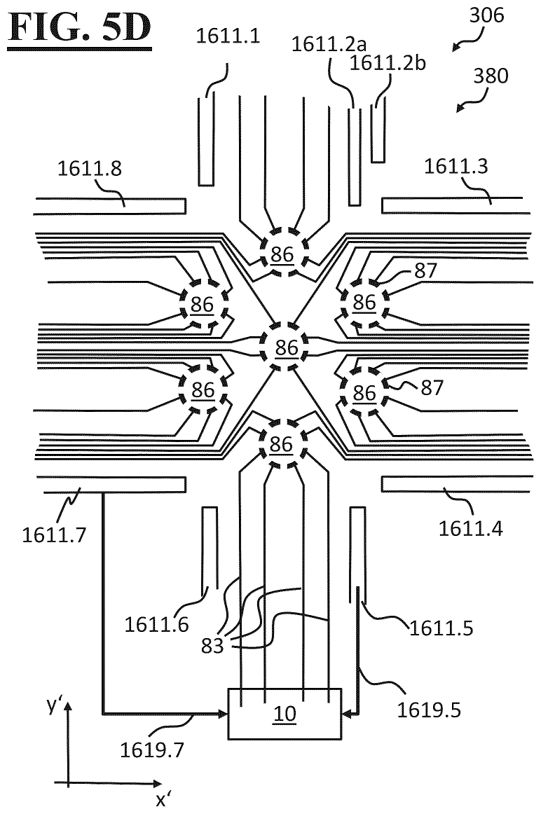

FIG. 5 shows a few examples of measuring apparatuses 1601. As first example of a measuring apparatus 1601.a, FIG. 5A shows an arrangement of three strain gauges 1611.1 to 1611.3. It is possible to determine length expansions in various directions independently of one another by way of a plurality of strain gauges arranged in different directions. For example, such strain gauges may be based on the piezo-resistive effect. Further strain gauges can be designed as optical strain gauges or as optical strain sensors such as fiber Bragg grating sensors, for example. Such optical strain gauges are advantageous in that they cannot cause any undesired interaction with an electron beam. As second example of a measuring apparatus 1601.b, FIG. 5B shows a capacitive sensor 1613 between two adjacent multi-aperture plates 306.1 and 306.2. As third example of a measuring apparatus 1601.c, FIG. 5C shows an interdigital structure 1615 as a strain sensor. Further measuring apparatuses 1601 may comprise temperature sensors or resistance measuring sections. Further, leakage currents which for example occur as a result of a contamination or degradation can be measured. Such a measuring apparatus is depicted in FIG. 4C. The creepage currents 1311 that lead to a charging of the active multi-aperture plate 306.1 can be dissipated, at least in part, via an ammeter 1617. Creepage currents IL can be measured via such a measuring apparatus 1601 in the form of an ammeter 1617.

However, creepage currents are not restricted to flowing from the first multi-aperture plate 304 to the active multi-aperture plate 306.1 and can impair the function of the active multi-aperture plate 306.1. During operation, electrodes are charged in targeted fashion in an active multi-aperture plate 306.1, for example in order to generate deflecting or focusing electric fields. An electrode can be charged by applying a voltage via a DAC. To set or maintain the voltage, a current flows via a DAC between the control unit 10 and the active multi-aperture plate 306.1. However, creepage and leakage currents 1311c and 1311d may in this case also be conducted from the active multi-aperture plate 306.1 to the first multi-aperture plate 304 and be superimposed there on the current measurement of the outflowing current IA. Hence, a current control of a particle source 301, for example, becomes faulty since the control signal (given by the outflowing current IA, which is ideally proportional to the absorbed particle current) is already faulty. For example, creepage and leakage currents from multiple or all electrodes may superimpose, whereby a significant total current may form as creepage and leakage current and may be orders of magnitude larger than the current flowing to or from an individual electrode.

FIG. 4D shows a further example of an embodiment. The multi-aperture arrangement or micro-optical unit 305 of this embodiment comprises a further, conductive plate 361, which forms a dissipation layer, between a first multi-aperture plate 304 and an active multi-aperture plate 306.1. Creepage currents 1311a and 1311b from the first multi-aperture plate 304 and creepage currents 1311c and 1311d from the active multi-aperture plate 306.1 initially flow to this dissipation layer 361, which has a low resistance connection to ground, for example. Creepage currents IL can be measured on this connection using an ammeter 1617 without this impairing a source current measurement IA or a function of an active component of the active multi-aperture plate 306.1.

FIG. 4E shows a further embodiment of an indirect creepage current measurement. In the example of FIG. 4E, the current supplied to an active multi-aperture plate 306 is compared to the current flowing away from the active multi-aperture plate 306. The electrodes of the multi-aperture plate 306 are controlled by a multi-channel DAC, wherein one DAC channel controls e.g. one electrode (optionally also a plurality of electrodes). The DAC is fed a supply voltage which supplies the power or current for the output voltages. In the ideal case, the sum of all currents into or out of the DAC is very low, for example 0. Thus, the sum of the currents of all DAC outputs is also reflected in the supply lines, and is summed there to form the current DAC-internally. In the ideal state, i.e. without contamination of or damage to the system, the difference between the current supplied and conducted away should therefore correspond to a predetermined difference, which for example can be ascertained by way of a calibration. Deviations from this difference are indications of leakage currents or creepage currents as a result of damage to or contamination of the micro-optical unit 305. FIG. 4E shows an example of a micro-optical unit 305 with a section of the control unit 10. The control unit initially senses a source current IA from the first multi-aperture plate 304. Further, the control unit is connected to a dissipation layer 361 for the purpose of sensing a leakage current IL. Further, the control unit 10 is connected to the active multi-aperture plate 306 via a DAC (digital to analog converter). The control unit 10 and the DAC are designed to generate predetermined individual voltage values at each electrode of the multiplicity of electrodes of the active multi-aperture plate 306. At the same time, the control unit comprises a current supply DC for the generation of the voltages. Voltages supplied to the DAC are generated by way of a voltage regulator UR. The current 391 supplied to the system of voltage regulator, ASIC and active multi-aperture plate 306 and the current 393 flowing out of the same system are measured in a differential ammeter DI (1601). Typical currents for controlling a DAC or an active multi-aperture plate 306 are of the order of a few mA to 100 mA. In the ideal state, differential currents in the range of a few nA to some μA are expected. The differential current in the ideal state is measured and stored as predetermined differential current. The differential current measured by the differential ammeter DI during operation is compared with the predetermined differential current, and the deviation from the predetermined differential current and the leakage current IL measured at the dissipation layer 361 are analyzed in the signal processor 820. As a result, the regulation of the source current in the control unit 810 and the control of the active multi-aperture plate 306 can be corrected. Cleaning or a replacement of the micro-optical unit 305 can be triggered as a further result. Therefore, the differential ammeter DI is a further example of a measuring apparatus 1601 for monitoring or sensing the state of a micro-optical unit 305.

Thus, FIG. 4E also describes an example of an apparatus (1701) for controlling an active multi-aperture plate (306), consisting of the power supply DC, the differential ammeter DI, a voltage regulator UR, and an ASIC, wherein the power supply DC, the differential ammeter DI and the voltage regulator UR may be arranged outside of a vacuum separation wall 550. The measurement of the current difference between the current flowing to the DAC and the current flowing from the DAC is advantageous since the overall current is higher, and hence measurements can be carried out more easily or with a lower resolution. In contrast to a current measurement per electrode, this is advantageous since only one measurement channel is used outside of the vacuum chamber with separation wall 550.

FIG. 4F shows an example of a differential ammeter DI. The current 391 made available by the power or voltage supply in the direction of the voltage regulator UR is measured across a resistor R/shunt, just like the current 393 flowing back from the voltage regulator UR. The current measurement is implemented by measuring the voltage drop across the known resistors R/shunt and is amplified by way of a difference amplifier 891. Currents 391, 393 conducted there and back are compared in a further difference amplifier 891, and the analog signal is supplied to an analog-to-digital converter (ADC). The digital result of the difference measurement is supplied to the signal processor 820.

FIG. 5D shows a further example of an active multi-aperture plate 306 having a multiplicity of apertures 86, each with a multiplicity of electrodes 87 which form multi-pole elements for individual particle beams. The multiplicity of elements of the active multi-aperture plate 306 are only depicted in excerpts and only some are labeled with reference signs. The active multi-aperture plate 306 consists of an insulator 380, for example silicon dioxide. The respective eight electrodes 87 of each multi-pole element consist of e.g. conductive material, for example doped silicon. The electrodes are insulated from one another, i.e. for example separated from one another by a gap or an insulator. Each electrode 87 of the multi-pole elements is connected to a control unit 10 via electrical supply lines 83. The electrical supply lines 83 can be generated on the surface of the multi-aperture plate 306, for example by lithography, and can be formed from a metal, for example aluminum. The control unit 10 is configured to influence each of the multiplicity of individual beams during operation, for example to deflect or reshape these. In addition, eight strain sensors 1611.1 to 1611.8 are arranged on the surface of the active multi-aperture plate 306 and sense local expansions of the multi-aperture plate 306 at a plurality of positions and in a plurality of directions. The strain sensors 1611.1 to 1611.8 are connected to the control unit 10 by way of signal connections 1619.1 to 1619.8. For example, the strain sensors 1611.1 to 1611.8 may also consist of doped silicon such that they can already be shaped during the production by way of microsystems technology-type deposition and structuring processes. A further advantage of doped silicon consists in the fact that it can be used both for measuring strain and for measuring temperature. The comparison of the signals from a plurality of strain sensors 1611.2a and 1611.2b of different length allows the simultaneous and independent establishment of expansion and temperature.

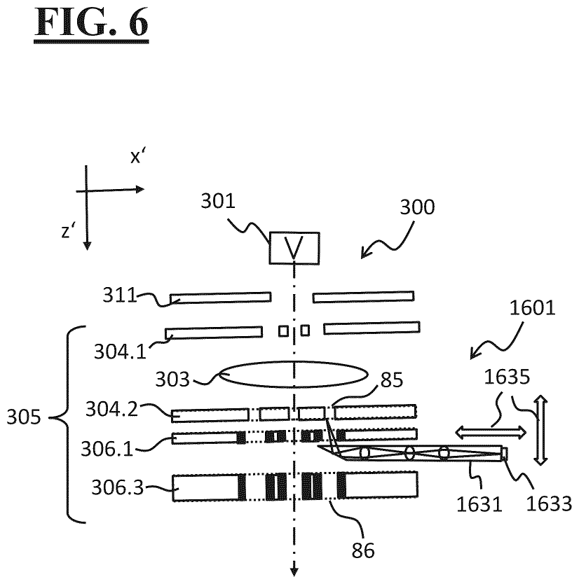

FIG. 6 shows a further example of a measuring apparatus 1601. The measuring apparatus 1601 consists of an optical measuring device, by which it is possible for example to determine contamination or roughness within an aperture 85, 86 in a multi-aperture plate 304, 306. To simplify matters, the sectional image in each case depicts only three apertures per multi-aperture plate. The measuring apparatus 1601 consists of an endoscope 1631 having a CMOS sensor 1633 which can be displaced over individual apertures 85, 86 in multi-aperture plates 304, 306 in the displacement directions 1635 via a displacement device not depicted here. This allows a contamination or degradation within an aperture 85, 86 to be detected in an inspection pause—for example when a wafer is changed—during the operation of the multi-beam system 1.

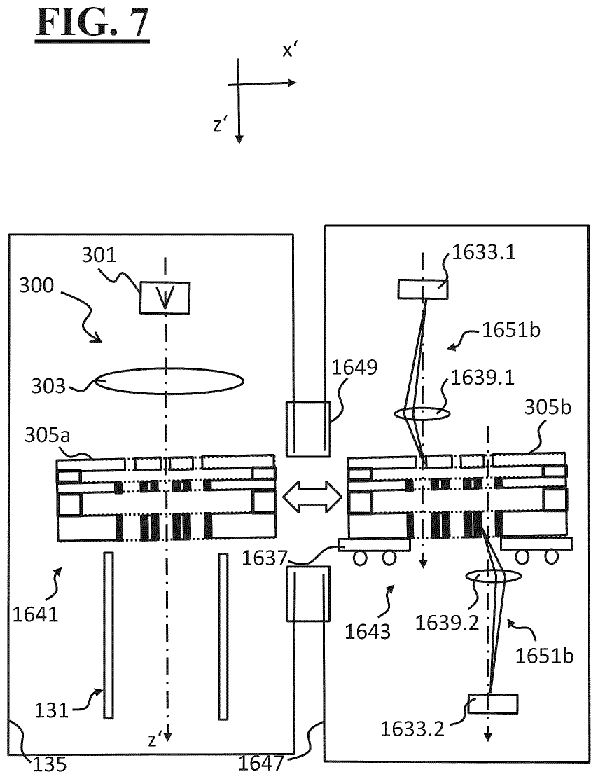

FIG. 7 shows a further example of a measuring apparatus 1601. The measuring apparatus 1601 consists of at least one optical measuring device 1633.1, 1633.2, which is arranged in an inspection chamber 1647. The micro-optical unit 305 is displaced from the operational position 1641 to the inspection position 1643 in an inspection pause, for example by way of a mounted displacement device 1637. It is also possible to provide two micro-optical units 305a, 305b in a multi-beam microscope 1, wherein, during operation, a first micro-optical unit 305a is operated in an operational position 1641 and a second micro-optical unit is examined for contamination in the inspection position 1643 using an optical measuring apparatus 1639.1, 1639.2. In the example shown, the inspection chamber 1647 is separated from the vacuum chamber 135 by a lock 1649, and the inspection chamber 1647 simultaneously serves as a cleaning chamber in which contamination can be removed by cleaning processes (plasma cleaning, thermal treatment). To this end, the displacement of the at least one multi-aperture plate or micro-optical unit into a cleaning chamber may be provided as a further step. Further, there can be a thermal or mechanical treatment in the servicing or cleaning position, deformations or positional changes of multi-aperture plates 304, 306 being corrected during the treatment by way of micro-actuators or local infrared irradiation, for example.

In general, it is possible to combine a plurality of different measuring apparatuses; for example, measuring apparatuses can be put together from the group of sensors consisting of temperature sensors, strain sensors, sensors for measuring leakage currents, optical measuring devices and optical endoscopes.

To be able to separate mechanical strains and temperature strains from one another, provision can also be made of a reference element with measuring apparatuses, wherein the reference element is arranged in a manner freed from loads, i.e. stored in a manner freed from forces or moments in particular. For example, a mechanical strain or positional change and a temperature strain can be separated from one another on the basis of the reference element.

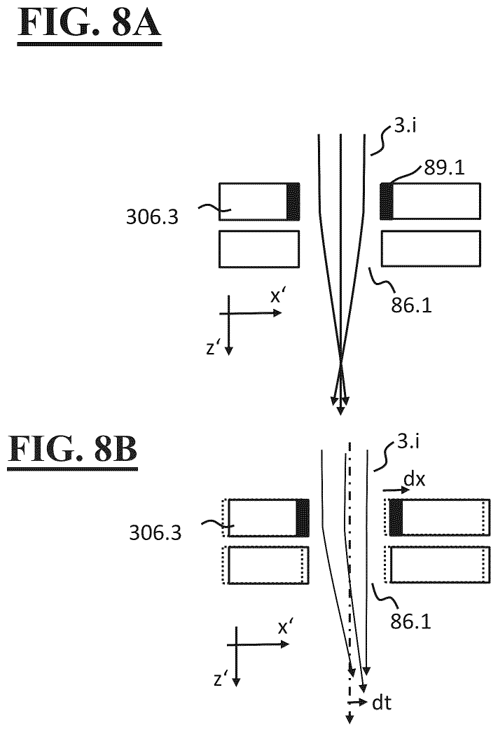

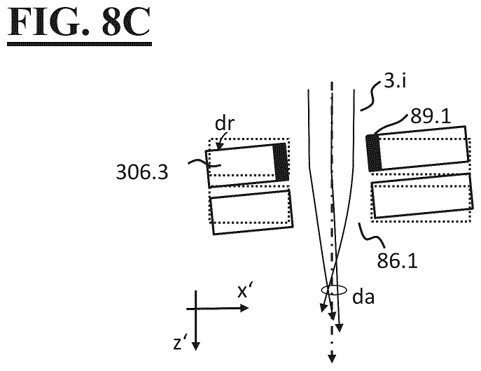

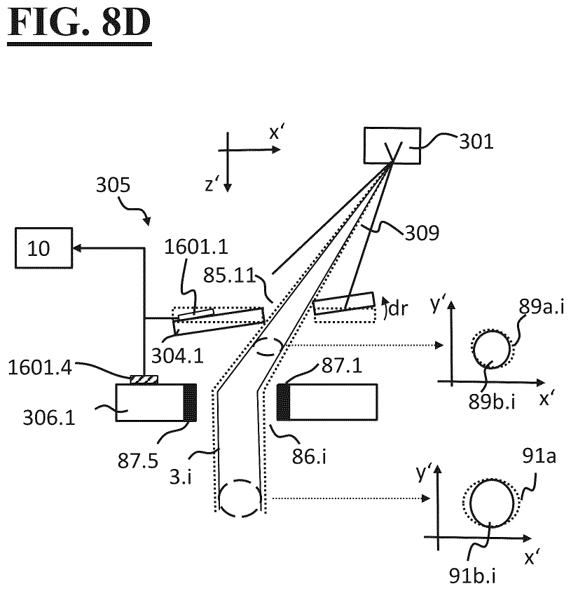

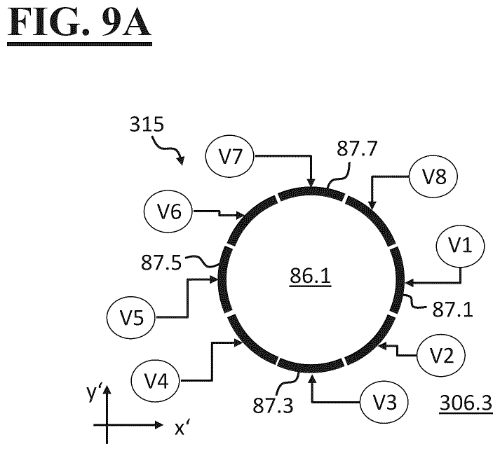

FIG. 8 illustrates a few examples of loads and effects. In details, the figures each show only one aperture in a respective multi-aperture plate. FIG. 8A shows the ideal case of a lens effect at a first aperture 86.1 in an active multi-aperture plate 306.3. FIG. 8B shows the case of a lateral displacement dx of the aperture 86.1 as a consequence of a volumetric expansion of the multi-aperture plate 306.3. The individual beam 3.i is no longer incident centrally on the electrostatic lens field and is deflected laterally through an angle dt. FIG. 8C shows the case of a deformation of the multi-aperture plate 306.3. In this case, an aperture 86.1 can be inclined relative to the incident individual beam through a local inclination angle dr, with the result that this leads to an aberration such as for example astigmatism or coma on the individual beam 3.i. The image point diameter therefore increases to a diameter da.

FIG. 8D shows a further load on a first filter plate 304.1 of a micro-optical unit 305 as described in FIG. 3A. In the example of FIG. 8D, the filter plate 304.1 has been deformed or bent as a result of heating, in a manner similar to what is depicted in FIG. 4A for an active multi-aperture plate 306. Thus, in the deformed state, the aperture 85.11 of the filter plate 304.1 is tilted relative to the z′-axis through the rotary angle dr. The tilt or rotation of the aperture 85.11 brings about a change in the cross-sectional shape of the aperture 85.11 for the incident electron beam 309, and a cross section of the individual particle beam 3.i following the passage through the aperture 85.11 has a shape 89b.i that deviates from the target shape 89a.i. Thus, following the deflection by the first active multi-aperture plate 306.1, the individual particle beam has an individual shape 91b.i which deviates from the target shape 91a. Since the local inclination angle dr is different at each aperture 85 in the filter plate 304.1 on account of the deformation of the filter plate 304.1, each cross section 91b.j (with j=1, . . . , J for the J individual beams) of each individual beam 3.j is consequently also slightly different, and each individual beam may for example have a slightly different directional anisotropy which leads to a deviation of the resolutions in different directions.

According to an embodiment of the disclosure, a multi-beam system 1 comprises a control unit 10, which acquires the multiplicity of measurement signals from the measuring apparatuses 1601 and hence determines a deformation of at least one multi-aperture plate 304, 306. An effect on the multiplicity of individual beams 3 like in the examples of FIG. 8 can be determined by way of the deformation determined thus. This effect can be compared with a demand regarding the accuracy of the multi-beam system 1. Proceeding from the effect, it is possible to make a prediction as to how long a multi-aperture plate 304, 306 can still be operated within a demand on the accuracy of the multi-beam system 1.

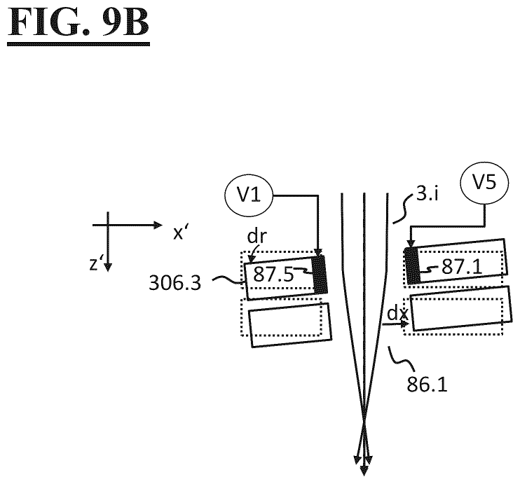

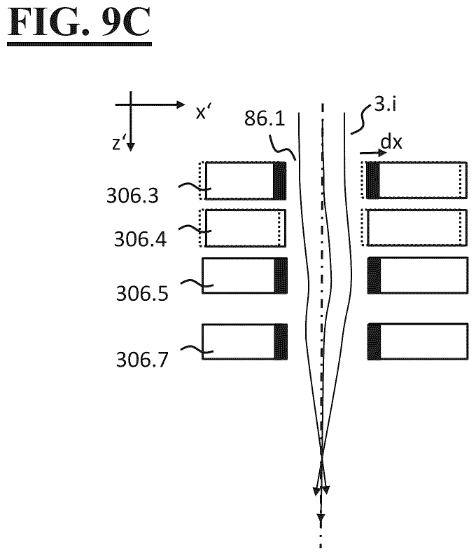

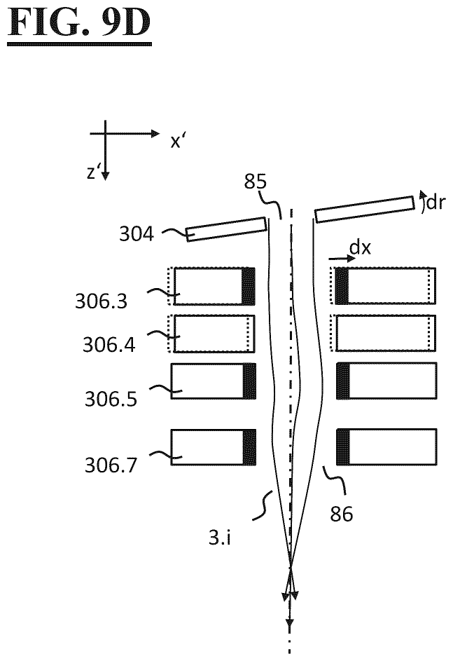

According to an embodiment of the disclosure, a multi-beam system 1 comprises a control unit 10 and at least one mechanism for compensating an effect of a deformation of the at least one multi-aperture plate 304, 306. An active multi-aperture plate 306 can be such a mechanism. FIG. 9A shows an example. In this example, the active multi-aperture plate 306.3 for generating a lens field is equipped with eight electrodes 87.1 to 87.8 rather than only a single ring electrode 87 (FIG. 9A is a plan view of an aperture 86.1). To generate a lens effect, all eight electrodes are supplied with the same voltages

V1 to V8 during operation. If a deformation which, as shown in FIG. 8C, would lead to an aberration is ascertained, then the voltages V1 to V8 are modified accordingly in order for example to compensate for an astigmatism (FIG. 9B).

FIG. 9C shows a further example. At least one further active multi-aperture plate 306.5, 306.7 can be provided as a mechanism for compensating an effect of a deformation of the at least one multi-aperture plate 304, 306. Two further active multi-aperture plates 306.5 and 306.7 are provided in the example of FIG. 9C; these are designed as multi-pole deflectors with an electrode arrangement at each aperture as shown in FIG. 9A. The electrodes are controlled by the control unit, for example in order to compensate for a beam offset (as shown in FIG. 8B).

FIG. 9D shows a further example for a compensation of an effect due to a local inclination angle dr at the filter plate 304. An individual beam 3.i, which is generated at the aperture 85 in the filter plate 304, has an unwanted elliptical cross-sectional shape due to the local inclination angle dr as a consequence of a deformation due to heating. This elliptical shape can be compensated for by anamorphic electrostatic lens effects of the multi-aperture plates 306.5 and 306.7 designed as multi-pole array element, with the result that the beam cross section of each individual beam 3.j is identical and round or isotropic in a plane parallel to the image plane 101, as desired for an isotropic resolution.

Thus, the measuring mechanism 1601 render it possible even without additional measuring systems to establish an effect on the multiplicity of individual beams 3.j during operation. The mechanism for compensating an effect render it possible to at least partially compensate this effect. Hence, an operation of a multi-beam system 1 that meets the demands can be ensured over a relatively long period of time. In particular, it is possible to increase the throughput, for example by virtue of enabling a higher beam current of the electron source 301. An increased beam current leads to an elevated thermal load, especially on the first filter plate 304, and leads there to an increased volumetric expansion and deformation with the disadvantageous effect as depicted in FIG. 8D.

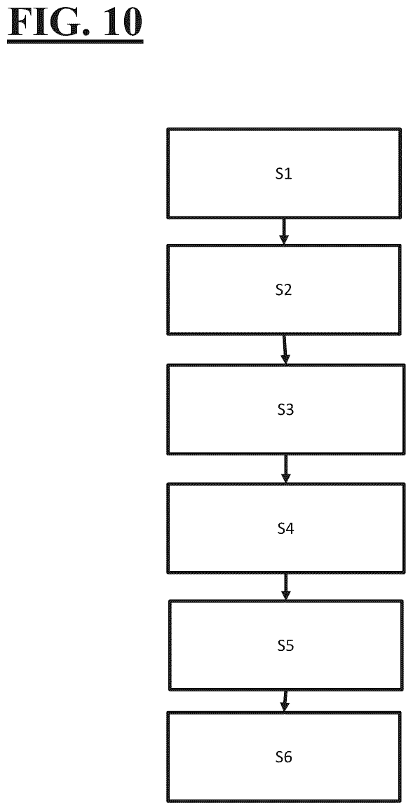

FIG. 10 illustrates a method for operating a multi-beam system 1. In a first step S1 during the operation of the multi-beam system 1, the method comprises an acquisition of measurement data from at least one measuring mechanism 1601. For example, step S1 comprises the acquisition of in each case three independent measurement data items from in each case three measuring mechanisms 1601.1 to 1601.3 from at least one multi-aperture plate 304 or 306. For example, step S1 comprises the acquisition of measurement data from a measuring mechanism such as temperature sensors, optical strain sensors, strain gauges, capacitive sensors or ammeters. For example, step S1 comprises the acquisition of measurement data from a measuring mechanism such as endoscopes 1631 or optical inspection systems 1639. For example, step S1 comprises the sensing of creepage currents IL using ammeters 1617 (see FIGS. 4C, 4D). For example, step S1 comprises the sensing of a differential current using a differential ammeter DI (see FIGS. 4E, 4F).

In step S2, the measurement data are converted into digital values and filtered, and compared with calibration values. For example, filtering may comprise averaging over time.

In an example, the deformation of the at least one multi-aperture plate 304, 306 is established from the filtered measurement data. This establishment of a deformation can be implemented on the basis of a model or, for example, by simplified finite element analyses.

Further, a contamination or degradation of multi-aperture plates 304, 306 or of insulating layers 380 between multi-aperture plates 304, 306 is deduced from the filtered measurement data.

An effect on the multiplicity of individual beams is established in step S3. This effect may comprise the positional deviation of single individual beams and aberrations of single individual beams. For example, aberrations may arise due to a modified filter effect of a first aperture 85.11 in a filter plate 304.1 on the beam cross section 87.1 or due to the passage through a tilted lens field. A beam offset may arise due to a deformation of an active multi-aperture plate 306.1 designed as a beam deflector or, for example, due to a laterally offset passage through a lens field. A lens effect can be reduced or increased as a result of a charging of a multi-aperture plate by creepage currents. This cumulative effect on the multiplicity of individual beams is compared with the demands on the multi-beam system 1, for example with a demand on resolution or an overlay accuracy (so-called overlay demand).

A compensation of the effect is established and set in step S4. To this end, control signals are established for the predetermined mechanism for compensating the effect and are supplied to the mechanism for compensating the effect. For example, the mechanism may be further active multi-aperture plates 306 or active multi-aperture plates 306 with a modified design. The influences of the mechanism for compensating the effect can be determined in advance during a calibration and can be stored in the control unit 10 of the multi-beam system 1. Using the influences as a starting point, a compensation of the effect is calculated and implemented.

The residual service life of the multi-beam system 1 is estimated in step S5. As explained above, permanent deformations or degradation may occur. In other examples, deformations or a contamination may increase continually during operation. A permanent deformation and the continual increase of a deformation lead to effects becoming ever more pronounced. For example, a compensation according to step S4 is no longer possible above a predetermined size of an effect, for example because an adjustment range of a mechanism for compensation has been fully exploited or because higher order aberrations already occur and it is not possible to compensate these, thus rendering the demands on the multi-beam system 1 no longer achievable. The admissible adjustment range of a compensation mechanism and the maximum permissible higher order aberrations can be determined in advance. A residual service life is calculated in step S5 from the actual state of the multi-beam system 1 and the expected further changes. The expected changes may arise from a model-based simulation or from a linear extrapolation of a history of deformation states.

Servicing, a replacement of components or recalibration of the multi-beam system 1 is then implemented in step S6. For example, servicing may comprise a thermal treatment of the multi-aperture plates 304, 306. For example, a thermal treatment may at least partially resolve permanent deformations. Contaminations can be removed by way of a plasma treatment. For a component replacement, a deformed or degraded micro-optical unit element 305 can be replaced with a new micro-optical unit element 305. Certain effects of the deformations can be removed within the scope of a recalibration.

The disclosure can be described by the following clauses:

Clause 1: A multi-beam system (1) comprising:
a particle source (301) for generating a particle beam (309),
a micro-optical unit (305) having at least one multi-aperture plate (304, 306),
a beam splitter (400) and an objective lens (102) for generating a multiplicity of focus points (5) in an image plane (101),
a control unit (10),
a measuring apparatus (1601) connected to the at least one multi-aperture plate (304, 306), the measuring apparatus (1601) supplying a measurement signal to the control unit (10), and
the control unit (10) being configured during operation to sense a change in shape, a contamination or a degradation of the at least one multi-aperture plate (304, 306) from the measurement signal.

Clause 2: The multi-beam system (1) according to clause 1, wherein the at least one multi-aperture plate (304, 306) comprises a filter plate (304) for generating a multiplicity of individual beams (3) from the particle beam (309).

Clause 3: The multi-beam system (1) according to clause 1 or 2, wherein the micro-optical unit (305) comprises an active multi-aperture plate (306, 306.1, 306.2, 306.3) for influencing the multiplicity of individual beams (3).

Clause 4: The multi-beam system (1) according to any of clauses 1 to 3, wherein the measuring apparatus (1601) comprises at least one of the following measuring mechanisms: a strain sensor (1611), an interdigital structure (1615) for sensing a change in length, an ammeter (1617) for sensing a leakage current (1311).

Clause 5: The multi-beam system (1) according to clause 4, wherein the strain sensor (1611) is formed as an optical strain sensor, for example as a fiber Bragg grating sensor.

Clause 6: The multi-beam system (1) according to clause 4, wherein at least one strain sensor (1611) or interdigital structure (1615) is formed on a filter plate (304) or on an active multi-aperture plate (306, 306.1, 306.2, 306.3).

Clause 7: The multi-beam system (1) according to any of clauses 4 to 6, wherein the micro-optical unit (305) further comprises a conductive dissipation layer (361) for dissipating a leakage current (1311) via the ammeter (1617) for the purpose of sensing the leakage current (1311).

Clause 8: The multi-beam system (1) according to any of clauses 1 to 7, wherein the measuring apparatus (1601) further comprises a differential ammeter DI for sensing the leakage current (1311), the differential ammeter DI being designed to sense the difference between a current (391) flowing to an active multi-aperture plate (306) and a current (393) flowing from the active multi-aperture plate (306).

Clause 9: The multi-beam system (1) according to any of clauses 1 to 8, wherein the control unit (10) is further designed to determine an effect on at least one individual beam (3) from the change in shape, a contamination or a degradation of the at least one multi-aperture plate (304, 306).

Clause 10: The multi-beam system (1) according to clause 9, further comprising at least one compensation element for at least partial compensation of the effect on at least one individual beam (3), with the control unit (10) being designed to establish a control signal for the compensation element and supply the control signal to the compensation element.

Clause 11: The multi-beam system (1) according to clause 10, wherein the at least one compensation element comprises an active multi-aperture plate (306.3, 306.5, 306.7) with an array of multi-pole elements (315).

Clause 12: The multi-beam system (1) according to any of clauses 1 to 8, further comprising a displaceable measuring mechanism (1631) and a positioning element (1635) for positioning the displaceable measuring mechanism (1631) for the purpose of inspecting at least one aperture (85, 86) in a multi-aperture plate (304, 306).

Clause 13: The multi-beam system (1) according to any of clauses 1 to 12, further comprising a cleaning chamber (1647) and a positioning device (1643) for positioning at least one component of the micro-optical unit (305) in the cleaning chamber (1647).

Clause 14: The multi-beam system (1) according to clause 13, wherein at least one measuring mechanism (1651) for inspecting at least one aperture (85, 86) in a multi-aperture plate (304, 306) is arranged in the cleaning chamber (1647).

Clause 15: The multi-beam system (1) according to any of clauses 1 to 14, wherein the first filter plate (304) comprises a multiplicity of elliptical aperture openings (85), the elliptical shape of which is designed in accordance with a subsequent beam deflection of each individual beam (3) such that each individual beam has the same round cross-sectional area (113) in a plane (111) parallel to the image plane (101).

Clause 16: The multi-beam system (1) according to clause 15, wherein the at least one compensation element comprises two active multi-aperture plates (306.5, 306.7) for at least partial compensation of the effect on at least one individual beam (3.i), the control unit (10) being designed such that, during operation, the at least one individual beam (3.i) has a round cross-sectional area (113) in a plane (111) parallel to the image plane (101).

Clause 17: A method for operating a multi-beam system (1), comprising the following steps while performing an inspection task on a wafer (7) using a multiplicity of individual beams (3):
acquiring measurement signals from a measuring apparatus (1601) connected to at least one multi-aperture plate (304, 306) or a dissipation layer (361) of a micro-optical unit (305),
establishing a current type of load from the measurement signals, wherein a type of load comprises a length extension, a deformation, a contamination or a degradation of the at least one multi-aperture plate (304, 306),
determining an effect of the current type of load on the imaging properties of at least one individual beam (3.i).

Clause 18: The method according to clause 17, wherein the determination of an effect comprises a determination of a cross-sectional area (113) of at least one individual beam (3.i) in a plane (111) parallel to the image plane (101).

Clause 19: The method according to clause 17 or 18, wherein the steps of acquisition, establishment and determination are performed repeatedly during an inspection task.

Clause 20: The method according to any of clauses 17 to 19, wherein the establishment of the current load diagram comprises a model-based analysis or a finite element analysis.

Clause 21: The method according to any of clauses 17 to 20, further comprising a storage of the measurement signals and current load diagrams.

Clause 22: The method according to any of clauses 17 to 21, further comprising the following steps:
deriving at least one control signal for at least one compensation element (306.3, 306.5, 306.7) for at least partial compensation of the effect on the imaging properties of the at least one individual beam (3.i),
supplying the at least one control signal to the at least one compensation element (306.3, 306.5, 306.7).

Clause 23: The method according to any of clauses 17 to 22, further comprising the following steps:
introducing a measuring mechanism (1631) for inspecting at least one aperture (85, 86) in at least one multi-aperture plate (304, 306),
sensing a contamination, a shape deviation or a roughness within at least one aperture (85, 86).

Clause 24: The method according to any of clauses 17 to 23, further comprising the following steps:
deriving, from at least one load diagram, a remaining service life of the multi-beam system (1) which meets a demand with respect to the imaging properties of the multiplicity of individual beams (3),
initiating servicing, cleaning or a replacement of the at least one multi-aperture plate (304, 306) of the micro-optical unit (305).

Clause 25: The method according to clause 24, further comprising a displacement of the at least one multi-aperture plate (304, 306) or micro-optical unit (305) into a cleaning chamber (1647).

Clause 26: A multi-beam system (1) comprising
a micro-optical unit (305) having a filter plate (304) comprising a multiplicity of apertures (85) for generating a multiplicity of individual beams (3),
an objective lens (102) generating a multiplicity of focus points (5) of the multiplicity of individual beams (3) in an image plane (101), and
a beam splitter (400) deflecting the multiplicity of individual beams (3) through a deflection angle (109) greater than 0°,
wherein the first filter plate (304) comprises a multiplicity of apertures (85) with an elliptical cross-sectional shape, whose elliptical shape is designed in accordance with a subsequent beam deflection of each individual beam (3) such that each individual beam has the same round cross-sectional area (113) in a plane (111) parallel to the image plane (101).

Clause 27: The multi-beam system (1) according to clause 26, wherein each elliptical cross-sectional shape of the multiplicity of apertures (85) in the filter plate (304) is designed to compensate an effect of the deflection angle (109) of the beam splitter (400) on each individual beam (3), with the result that each individual beam (3) has a round cross-sectional area (113) in the plane (111) parallel to the image plane (101).

Clause 28: The multi-beam system (1) according to clause 26 or 27, further comprising at least one active multi-aperture plate (306, 306.1, 306.2, 306.3, 306.5, 306.7).

Clause 29: The multi-beam system (1) according to clause 28, wherein at least one active multi-aperture plate (306.1) comprises a multiplicity of deflectors designed to individually deflect each individual beam in an axis direction and wherein at least one aperture (85) in the filter plate (304) has an individual elliptical cross-sectional shape for compensating an effect of the deflection of the at least one active multi-aperture plate (306.1).

Clause 30: The multi-beam system (1) according to clause 28 or 29, wherein at least one active multi-aperture plate (306.1) comprises a multiplicity of deflectors designed to individually deflect each individual beam in an axis direction and wherein at least one aperture (85) in the filter plate (304) has an individual elliptical cross-sectional shape in order to compensate an effect of the deflection angle (109) of the beam splitter (400) and an effect of the deflection of the at least one active multi-aperture plate (306.1) on each individual beam (3) such that each individual beam (3) has a round cross-sectional area (113) in the plane (111) parallel to the image plane (101).

Clause 31: The multi-beam system (1) according to any of clauses 26 to 30, wherein the diameters of the apertures (85) with elliptical cross-sectional shape additionally have a parameter dependent on the position of an individual beam in order to compensate an image shell error and an image plane tilt.

Clause 32: The multi-beam system (1) according to any of clauses 26 to 31, wherein the at least one filter plate (304) or at least one active multi-aperture plate (306, 306.1, 306.2, 306.3, 306.5, 306.7) is connected to a measuring apparatus (1601) which supplies a measurement signal to a control unit (10) of the multi-beam system (1) and wherein the control unit (10) is configured during operation to determine a change in a shape, a contamination or a degradation of the at least one filter plate (304) or at least one active multi-aperture plate (306, 306.1, 306.2, 306.3, 306.5, 306.7) from the measurement signal.

Clause 33: The multi-beam system (1) according to any of clauses 26 to 32, wherein the micro-optical unit (305) further comprises a conductive dissipation layer (361) for dissipating a leakage current (1311).

Clause 34: The multi-beam system (1) according to either of clauses 32 and 33, wherein the measuring apparatus (1601) comprises at least one of the following measuring mechanisms: a strain sensor (1611) or an interdigital structure (1615) for sensing a change in length, a capacitive sensor (1613) for sensing a change in distance, an ammeter (1617) or a differential ammeter DI for sensing a leakage current.

Clause 35: The multi-beam system (1) according to any of clauses 32 to 34, further comprising at least one compensation element (306.3, 306.5, 306.7) for at least partial compensation of an effect of the change in shape, the contamination or the degradation of the at least one filter plate (304) or at least one active multi-aperture plate (306, 306.1, 306.2, 306.3, 306.5, 306.7), wherein the control unit (10) is designed to establish a control signal for the compensation element (306.3, 306.5, 306.7) from the change in shape, the contamination or the degradation, and to supply the control signal to the compensation element.

Clause 36: The multi-beam system (1) according to clause 35, wherein the compensation element comprises an active multi-aperture plate (306.3, 306.5, 306.7) with an array of multi-pole elements.

Clause 37: The multi-beam system (1) according to any of clauses 26 to 36, further comprising a cleaning chamber (1647) and a positioning device (1643) for positioning at least one filter plate (304) or at least one active multi-aperture plate (306, 306.1, 306.2, 306.3, 306.5, 306.7) in the cleaning chamber (1647).

Clause 38: An apparatus (1701) for controlling an active multi-aperture plate (306) for a multi-beam particle beam system (1), wherein the active multi-aperture plate (306) comprises a multiplicity of electrodes (87) arranged at a multiplicity of apertures (86), wherein the apparatus (1701) is designed during the operation to supply each electrode (87) with a voltage for individually influencing individual particle beams (3) of the multi-beam particle beam system (1), wherein the apparatus (1701) is characterized in that the apparatus (1701) comprises a differential ammeter DI for sensing the difference between a current (391) flowing to the active multi-aperture plate (306) and a current (393) flowing away from the active multi-aperture plate (306).

Clause 39: A micro-optical unit (305) for generating or influencing a multiplicity of individual particle beams (3) of a multi-beam particle beam system (1), comprising a first multi-aperture plate or filter plate (304), an active multi-aperture plate (306) having a multiplicity of electrodes (87), and a conductive dissipation layer (361) between the filter plate (304) and the active multi-aperture plate (306), wherein every plate (304, 306, 361) is separated from others by insulators (380) and wherein the conductive dissipation layer (361) is connected to ground for dissipating leakage currents (1311).

Clause 40: The micro-optical unit (305) according to clause 39, wherein the conductive dissipation layer (361) is further connected to ground via an ammeter (1617) for the purpose of measuring a leakage current (1311). However, the disclosure is not restricted to the clauses and combinations or modifications of the clauses are likewise possible and incorporated.

### A LIST OF REFERENCE SIGNS IS PROVIDED

1 Multi-beam particle microscope or multi-beam system
3 Individual particle beam or multiplicity of individual particle beams
5 Beam spots
7 Object, e.g. wafer
9 Secondary particle beam or multiplicity of secondary particle beams
10 Control unit
15 Object surface
83 Electrical supply line
85 Aperture in a filter plate
86 Aperture in an active array element
87 Electrodes
89 Beam cross section downstream of the first aperture
91 Beam cross section after the deflection
101 Object plane
102 Objective lens
103 Electromagnetic lens
105 Optical axis of the objective lens
109 Deflection angle of the primary beams by the beam splitter
111 Plane parallel to the image plane 101
113 Beam cross sections
115 Pupil distribution
117 Pupil plane
131 Beam tube
135 Vacuum chamber
200 Projection system
209 Particle detector
210 Electromagnetic lenses
215 Incidence locations of the secondary beams
220 Second collective deflector
222 Contrast stop
300 Beam generation device
301 Particle source
303 Condenser lenses
304 Filter plate
305 Multi-aperture arrangement or micro-optical unit
306 Multi-aperture plate or active array element
307 Field lens
308 Field lens
309 Particle beam
311 Stop
313 Contamination layer
315 Multi-pole element
323 Focus point
325 Intermediate image surface
361 Dissipation layer
380 Insulator
382 Membrane
391 Inflowing current
393 Outflowing current
400 Beam splitter
500 Beam deflection system or scanner
550 Vacuum enclosing wall
891 Difference amplifier
1307 Fixed connection points
1309 Flexible bearing points
1311 Leakage current
1601 Measuring apparatus
1611 Strain gauge
1613 Capacitive sensor
1615 Interdigital structure
1617 Ammeter
1619 Electrical signal connection
1631 Displaceable measuring mechanism
1633 Camera sensor
1635 Positioning device
1637 Positioning device
1639 Optical inspection system
1641 Operational position
1643 Inspection and servicing position
1647 Cleaning chamber
1649 Lock
1651 Measuring mechanism
1701 Apparatus for controlling an active multi-aperture plate

1. A multi-beam system, comprising:
a particle source configured to generate a particle beam;
a micro-optical unit comprising a multi-aperture plate;
a beam splitter and an objective lens configured to generate a multiplicity of focus points in an image plane;
a control unit; and
a measuring apparatus connected to the multi-aperture plate,
wherein:
the measuring apparatus is configured to supply a measurement signal to the control unit; and
the control unit is configured to sense, based on the measurement signal, at least one parameter selected from the group consisting of a change in a shape of the multi-aperture plate, a contamination of the multi-aperture plate, and a degradation of the multi-aperture plate.

2. The multi-beam system of claim 1, wherein the multi-aperture plate comprises a filter plate configured to generate a multiplicity of individual beams from the particle beam.

3. The multi-beam system of claim 1, wherein the micro-optical unit comprises an active multi-aperture plate configured to influence the multiplicity of individual beams.

4. The multi-beam system of claim 1, wherein the measuring apparatus comprises at least one member selected from the group consisting of a strain sensor, an interdigital structure configured to sense a change in length, and an ammeter configured to sense a leakage current.

5. The multi-beam system of claim 1, wherein measuring apparatus comprises an optical strain sensor.

6. The multi-beam system of claim 1, wherein:
the measuring apparatus comprises at least one member selected from the group consisting of a strain sensor and an interdigital structure configured to sense a change in length; and
the at least one member is on the multi-aperture plate.

7. The multi-beam system of claim 1, wherein:
the measuring apparatus comprises an ammeter configured to sense a leakage current; and
the micro-optical unit further comprises a conductive dissipation layer configured to dissipate a leakage current via the ammeter.

8. The multi-beam system of claim 1, wherein the measuring apparatus further comprises a differential ammeter configured to sense a leakage current, the differential ammeter being configured to sense a difference between a current flowing to an active multi-aperture plate and a current flowing from the active multi-aperture plate.

9. The multi-beam system of claim 1, wherein the control unit is configured to determine an effect on at least one individual beam due to the at least one parameter.

10. The multi-beam system of claim 9, further comprising a compensation element configured to at least partially compensate the effect on the at least one individual beam, wherein the control unit is configured to provide a control signal to the compensation element.

11. The multi-beam system of claim 10, wherein the compensation element comprises an active multi-aperture plate comprising an array of multi-pole elements.

12. The multi-beam system of claim 1, further comprising:
a displaceable measuring mechanism; and
a positioning element configured to position the displaceable measuring mechanism to inspect an aperture in the multi-aperture plate.

13. The multi-beam system of claim 1, further comprising:
a cleaning chamber; and
a positioning device configured to position a of the micro-optical unit in the cleaning chamber.

14. The multi-beam system of claim 13, wherein the cleaning chamber comprises a mechanism configured to inspect an aperture in the multi-aperture plate.

15. The multi-beam system of claim 2, wherein the first filter plate comprises a multiplicity of elliptical aperture openings configured according to a subsequent beam deflection of each individual beam so each individual beam has the same round cross-sectional area in a plane parallel to the image plane.

16. The multi-beam system of claim 15, further comprising a compensation element configured to at least partially compensate the effect on the at least one individual beam, wherein:
the control unit is configured to provide a control signal to the compensation element;
the element comprises two active multi-aperture plates configured to at least partially compensate the effect on at least one individual beam;
the control unit is configured so that the at least one individual beam has a round cross-sectional area in a plane parallel to the image plane.

17. A method, comprising:
performing an inspection task on a wafer using a multiplicity of individual beams generated by a multi-beam system; and
while performing the inspection task on the wafer:
acquiring measurement signals from a measuring apparatus connected to a multi-aperture plate or a dissipation layer of a micro-optical unit of the multi-beam apparatus;
establishing a current type of load from the measurement signals, the current type of load comprising at least one parameter selected from the group consisting of a length extension of the multi-aperture plate, a deformation of the multi-aperture plate, a contamination of the multi-aperture plate, and a degradation of the multi-aperture plate; and
determining an effect of the current type of load on the imaging properties of at least one individual beam.

18. The method of claim 17, wherein determining the effect comprises determining a cross-sectional area of at least one individual beam in a plane parallel to an image plane of the multi-beam apparatus.

19. The method of claim 17, further comprising repeatedly performing the acquisition, establishment and determination.

20. The method of claim 17, wherein establishing the current load diagram comprises using a model-based analysis or a finite element analysis.

21.-25. (canceled)
